(19) United States
(12) Patent Application Publication
(10) Pub. No.: US 2023/0378144 A1
(43) Pub. Date: Nov. 23, 2023

(54) STACKED PACKAGING STRUCTURE AND POWER CONVERTER

(71) Applicant: Silergy Semiconductor Technology (Hangzhou) LTD, Hangzhou (CN)

(72) Inventor: Shijie Chen, Hangzhou (CN)

(21) Appl. No.: 18/141,510

(22) Filed: May 1, 2023

(30) Foreign Application Priority Data
May 20, 2022 (CN) 202210556968.7

(51) Int. Cl. H01L 25/16; H01L 23/31; H01L 23/00; H02M 3/00

(52) U.S. Cl. CPC H01L 25/16; H01L 23/3157; H01L 24/05; H01L 24/32; H02M 3/003; H01L 23/293

(57) ABSTRACT

A stacked packaging structure can include: a lead frame; a die located on a first surface of the lead frame; an electrical interconnection structure located above the die and configured to be electrically connected with corresponding electrodes of the die; a diode located on the electrical interconnection structure; and where a lower surface of the diode is electrically connected to the electrical interconnection structure, and the electrode on an upper surface of the diode is connected to the corresponding pins of the lead frame.

### RELATED APPLICATIONS

This application claims the benefit of Chinese Patent Application No. 202210556968.7, filed on May 20, 2022, which is incorporated herein by reference in its entirety.

### FIELD OF THE INVENTION

The present invention generally relates to the field of semiconductor technology, and more particularly to packaging structures and power converters.

### BACKGROUND

With increasing functionality, performance, and integration of integrated circuits, as well as the emergence of new types of integrated circuits, packaging technology plays an increasingly important role in integrated circuit products. Along these lines, packaging technology accounts for an increasing portion of the value of an entire electronic system.

### BRIEF DESCRIPTION OF THE DRAWINGS

FIG. 1 is a structural schematic diagram of an example half bridge drive circuit.

FIG. 2 is a cross-sectional view of an example stacked packaging structure, in accordance with embodiments of the present invention.

FIG. 3 is a top view of the example stacked packaging structure, in accordance with embodiments of the present invention.

FIG. 4 is a structural diagram of an example electrical interconnection structure in the stacked packaging structure, in accordance with embodiments of the present invention.

FIG. 5 is an example power converter, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

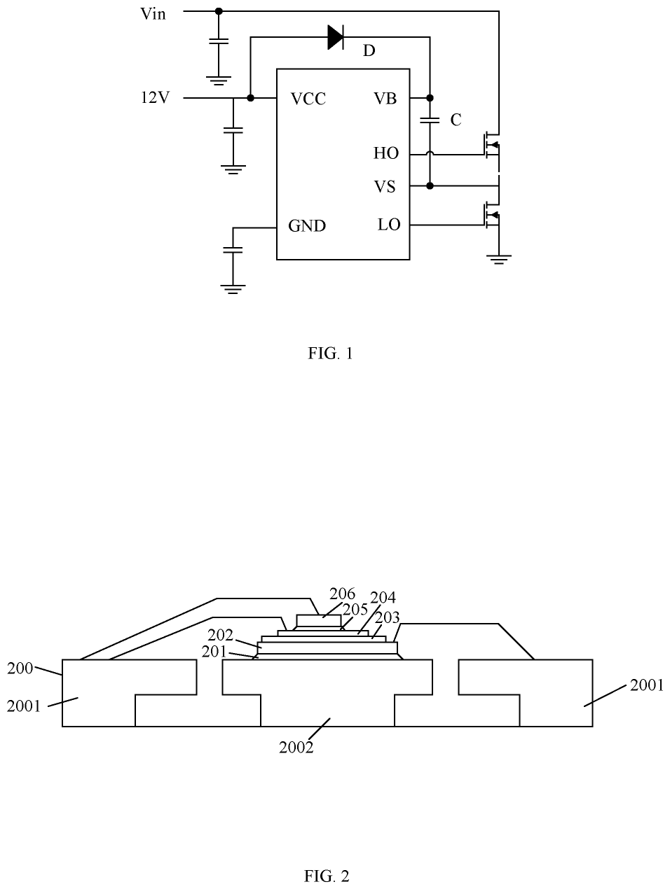

Referring now to FIG. 1, shown is a structural schematic diagram of an example half bridge drive circuit. In high-voltage integrated circuits, bootstrap diodes are commonly used as a half-bridge drive circuit, as shown. When floating power supply terminal VS is at a low-voltage level, power supply VCC can charge bootstrap capacitor C through bootstrap diode D, while supplying power to high-voltage side power supply VB. When floating power supply terminal VS is at high-voltage level, the voltage on floating power supply terminal VS may exceed the voltage on power supply VCC through bootstrap capacitor C, and bootstrap diode D may enter a reverse cut-off state. In this case, the circuit on the high-voltage side can be powered by bootstrap capacitor C. In some high-voltage integrated circuits, bootstrap diode D can be formed using silicon on insulator (SOI) technology or CMOS technology. However, SOI technology requires a specific substrate, and relatively few wafer fabs have such foundry capabilities. Additionally, the required wafer costs can be high. For CMOS processes, the control may be relatively complex and the circuit design requirements relatively high.

In particular embodiments, a stacked packaging structure can include a lead frame, a die located on a first surface of the lead frame, a patterned first insulation layer, a diode, and an electrical interconnection structure. The patterned first insulation layer can be located on the surface of the die for voltage isolation and protection, and may selectively expose the metal structure with corresponding polarity of the die. The electrical interconnection structure can be located above the first insulation layer for electrical connection with the exposed metal structure of the die, and the electrode of the diode can be led out to facilitate electrical connection. The diode may be located on the electrical interconnection structure, whereby its lower surface is electrically connected to the electrical interconnection structure, and the electrode on the upper surface can connect to the corresponding pins of the lead frame. For example, the diode can be a regular silicon based diode. Also for example, the lead frame can be a QFN lead frame, with characteristics of relatively small volume and light weight. In this example, the stacked packaging structure can encapsulate the die and diode together using suitable processes, the technical barriers caused by the use of SOI or CMOS technology for diode preparation can be substantially avoided, and the requirements for diode formation also reduced. In addition, the layout of the die in this example packaging structure is more flexible, and the number of pins in the packaging structure not limited, thus further reducing the packaging volume.

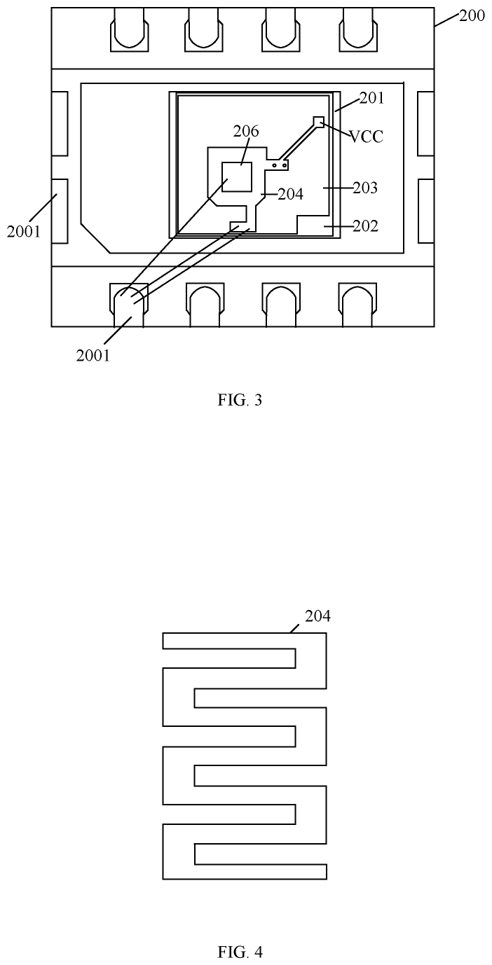

Referring now to FIG. 2, shown is a cross-sectional view of an example stacked packaging structure, in accordance with embodiments of the present invention. In this particular example, the packaging structure can include lead frame 200, die 202, patterned insulation layer 203, electrical interconnection structure 204, and diode 206. Die 202 can be installed on a first surface of lead frame 200, and patterned insulation layer 203 may be located on an upper surface of die 202 for voltage isolation and protection of die, and to selectively expose the metal structures with corresponding electrodes of die 202. Patterned electrical interconnection structure 204 can be located on an upper surface of insulation layer 203 to electrically connect with the exposed metal structure of die 202. Diode 206 may be located above electrical interconnection structure 204. A lower surface of diode 206 can be electrically connected to electrical interconnection structure 204, an electrode of an upper surface of diode 206 can connect to the corresponding pin of lead frame 200 for electrically connecting the metal structure of the die to diode 206, and the electrode of diode 206 can be led out to facilitate electrical connection.

In this example, insulating layer 203 can include a polyimide material, and the insulating layer may be formed, e.g., by a PVD process, a CVD process, or a coating process. For example, insulation layer 203 may have a predetermined thickness for voltage isolation and protection of the die. The thickness of insulation layer 203 can be designed according to the process capacity of the factory and any warping problem caused by the insulating layer itself. For example, the thickness of insulation layer 203 may not be greater than 10 um. In this example, the stacked packaging structure may utilize polyimide passivation packaging technology, with excellent performance, relatively simple process operation, and that is suitable for mass production of products. Electrical interconnection structure 204 can be a metal redistribution layer having at least two different types of metal layers. For example, electrical interconnection structure 204 can include a Cu metal layer, a Ni metal layer, and an Au metal layer, which may be formed through an electroplating process. In alternative examples, electrical interconnection structure 204 can include suitable other metals and/or processes. For example, the thickness of electrical interconnection structure 204 may not be less than 8 um.

The packaging structure can also include adhesive layer 201 located between lead frame 200 and die 202, as well as adhesive layer 205 located between electrical interconnection structure 204 and diode 206. Adhesive layer 201 can be used to install die 202 on lead frame 200, and adhesive layer 205 may be used to install the diode 206 on electrical interconnection structure 204. In this example, adhesive layers 201 and 205 can be conductive adhesives, and the thickness of adhesive layer 205 can be less than 10 um. In another example, adhesive layer 205 may be configured as a welding layer for welding diode 206. For example, the welding layer can include lead-free solder with a thickness range of from 10 um to 15 um.

The packaging structure can also include a patterned second insulation layer located above electrical interconnection structure 204, and selectively exposing the upper surface of electrical interconnection structure 204. Second insulation layer may be utilized in conjunction with electrical interconnection structure 204 to improve the contact surface of diode 206, thereby better serving as a fixed connection and support. In this example, the second insulation layer can be subjected to opening treatment to form an opening for selectively exposing the upper surface of electrical interconnection structure 204, thereby enabling electrical connection between the lower surface of the diode and the upper surface of the exposed electrical interconnection structure. For example, the size of diode may be greater than that of the opening of the second insulation layer, and at least one side of the diode may exceed the corresponding side of the opening of the second insulating layer by 20-50 um. For example, the second insulating layer can include a polyimide material, and the second insulating layer may be formed, e.g., by a PVD process, a CVD process, or a coating process.

In particular embodiments, the surface of lead frame 200 can be subjected to an etching process. The etching may begin from the upper surface of lead frame 200, and extend along the thickness direction of the lead frame, and stop in lead frame 200. Accordingly, the depth of the etching is less than the thickness of lead frame 200. A concave convex shape may be formed on the surface of lead frame 200, and the surface of the convex part can be the outer pin layer pattern of the lead frame. The pins of lead frame 200 can include second type pin 2001 distributed in the edge area of the lead frame, and first type pin 2002 distributed in the middle of the lead frame. For example, second type pin 2001 can be L-shaped, and first type pin 2002 may be T-shaped. In particular embodiments, according to circuit design requirements, the packaging structure can be combined from diode 206, electrical interconnection structure 204, and lead of die 202 to pin 2001, in order to provide circuit connections for the distribution of power and signals. Any suitable wire bonding arrangement can be utilized in certain embodiments.

Referring now to FIG. 3, shown is a top view of the example stacked packaging structure, in accordance with embodiments of the present invention. In this particular example, the top view structure of the packaging structure corresponds to the cross-sectional view in FIG. 2, showing each part of the packaging structure from bottom to top. Lead frame 200 can include pin 2001 located in its edge area, and pin 2002 located in its internal area. The packaging structure can include lead frame 200, die 202, insulation layer 203, electrical interconnection structure 204, and diode 206. The packaging structure further can also include adhesive layer 201 located between the base island of lead frame 200 and die 202, as well as adhesive layer 205 located between electrical interconnection structure 204 and diode 206. In this example, electrical interconnection structure 204 may respectively be led to pin VCC and pin 2001 to complete the bonding, and diode 206 can be led to pin 2001 to complete the bonding. Any suitable wire bonding arrangement can be utilized in certain embodiments.

Referring now to FIG. 4, shown is a structural diagram of an example electrical interconnection structure in the stacked packaging structure, in accordance with embodiments of the present invention. In some packaging structures, there can be a problem of layering caused by insufficient bonding force of the adhesive layer or contamination (e.g., rust) of the lead frame. In order to enhance the anti-layering ability, the packaging structure of particular embodiments may have undergone special processing on electrical interconnection structure 204. For example, electrical interconnection structure 204 can be configured as a cross toothed structure to enhance the bonding force of the electrical interconnection structure, and thus enhance its anti-layering ability, as shown in FIG. 4.

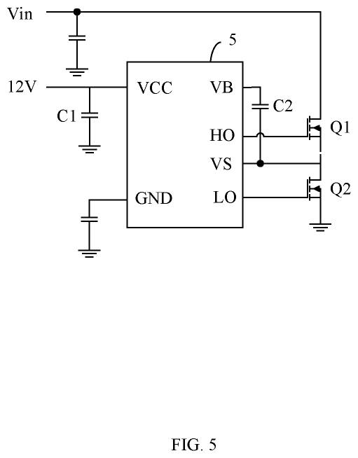

Referring now to FIG. 5, shown is an example power converter, in accordance with embodiments of the present invention. In this particular example, the power converter can include stacked packaging structure 5, as discussed above. Stacked packaging structure 5 can include pin VCC, pin VB, and pin VS. Inside packaging structure 5, an anode of the diode can be electrically connected to pin VCC, and a cathode of the diode may be electrically connected to pin VB. Capacitor C1 can connect between pin VCC and the ground potential of the power converter, and capacitor C2 can connect between pin VB and pin VS. Pin VS can connect to a common node of transistors Q1 and Q2 in the power converter. When a lower voltage is applied to pin VS, the voltage of pin VCC can be charged to capacitor C2 through the diode, while supplying power to pin VB. When a high voltage is applied to pin VS, the voltage on pin VS may exceed the voltage on pin VCC through capacitor C2, and the diode may enter a reverse cut-off state. In this case, the circuit on the high voltage side can be supplied with power through capacitor C2. In particular embodiments, such a stacked packaging structure can be applied to any suitable circuit topology, such as power converters and related circuitry.

In particular embodiments, a stacked packaging structure can be arranged whereby the die and the diode are packaged together by using the lead frame as the die carrier of the integrated circuit. Thus, the technical barrier caused by the diode being prepared by adopting SOI technology or CMOS technology can be substantially avoided, and limitations on the diode preparation method utilize may be reduced. In addition, the arrangement of the die in the packaging structure may provide more flexibility, and the number of pins of the packaging structure may not be limited, such that the packaging volume can be further reduced.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A stacked packaging structure, comprising:
a) a lead frame;
b) a die located on a first surface of the lead frame;
c) an electrical interconnection structure located above the die and configured to be electrically connected with corresponding electrodes of the die;
d) a diode located on the electrical interconnection structure; and
e) wherein a lower surface of the diode is electrically connected to the electrical interconnection structure, and the electrode on an upper surface of the diode is connected to the corresponding pins of the lead frame.

2. The stacked packaging structure of claim 1, further comprising an adhesive layer between the electrical interconnection structure and the diode for electrically connecting the electrical interconnection structure and the diode, and fixing both the electrical interconnection structure and the diode.

3. The stacked packaging structure of claim 2, wherein the adhesive layer is a conductive adhesive.

4. The stacked packaging structure of claim 1, further comprising a patterned second insulating layer located on the electrical interconnection structure to selectively expose an upper surface of the electrical interconnection structure.

5. The stacked packaging structure of claim 4, wherein the second insulating layer comprises an opening, and a lower surface of the diode is electrically connected with the exposed upper surface of the electrical interconnection structure through the opening of the second insulating layer.

6. The stacked packaging structure of claim 5, wherein at least one side of the diode exceeds the corresponding side of the opening of the second insulating layer by a distance from 20 um to 50 um.

7. The stacked packaging structure of claim 1, wherein a thickness of the first insulation layer is not greater than 10 um.

8. The stacked packaging structure of claim 1, wherein the electrical interconnection structure is configured as a cross toothed structure.

9. The stacked packaging structure of claim 1, wherein the electrical interconnection structure is a patterned metal redistribution layer configured to electrically connect the metal structure of the die to the diode, and to lead out the electrodes of the diode.

10. The stacked packaging structure of claim 9, wherein the electrical interconnection structure comprises at least one of: Cu metal layers, Ni metal layers, and Au metal layers.

11. The stacked packaging structure of claim 9, wherein a thickness of the electrical interconnection structure is not less than 8 um.

12. The stacked packaging structure of claim 1, further comprising a welding layer between the electrical interconnection structure and the diode for welding the diode.

13. The stacked packaging structure of claim 12, wherein the welding layer is configured as lead-free solder with a thickness of from 10 um to 15 um.

14. The stacked packaging structure of claim 4, wherein each of the first insulating layer and the second insulating layer comprises a polyimide.

15. The stacked packaging structure of claim 1, wherein the lead frame is a quad flat no-lead package (QFN) lead frame.

16. The stacked packaging structure of claim 1, wherein a group of metal leads are used to lead from the upper surface of the electrical interconnection structure and the upper surface of the diode to the corresponding pins of the lead frame respectively.

17. A power converter, comprising the package structure of claim 1, and further comprising:
a) a first pin, a second pin, and a third pin;
b) a first capacitor connected between the first pin and a ground potential of the power converter;
c) a second capacitor connected between the second pin and the third pin; and
d) wherein inside the package structure, an anode of the diode is electrically connected to the first pin, a cathode of the diode is electrically connected to the second pin, and the third pin is connected to a common node of that first transistor and the second transistor of the power converter.

18. The stacked packaging structure of claim 3, wherein a thickness of the adhesive layer is not more than 10 um.

19. The stacked packaging structure of claim 1, further comprising a patterned first insulating layer, wherein the first insulating layer is located on an upper surface of the die and selectively exposes the metal structures with electrodes on the upper surface of the die.

20. The stacked packaging structure of claim 5, wherein a size of diode is greater than a size of the opening of the second insulating layer.
